(19) United States
(12) Patent Application Publication
(10) Pub. No.: US 2010/0176394 A1
(43) Pub. Date: Jul. 15, 2010

(54) Thin film transistor and flat panel display device having the same

(75) Inventors: Jin-Seong Park, Yongin-city (KR); Yeon-Gon Mo, Yongin-city (KR); Jae-Kyeong Jeong, Yongin-city (KR); Min-Kyu Kim, Yongin-city (KR); Hyun-Joong Chung, Yongin-city (KR); Tae-Kyung Ahn, Yongin-city (KR); Eun-Hyun Kim, Yongin-city (KR)

Correspondence Address: ROBERT E. BUSHNELL & LAW FIRM, 2029 K STREET NW, SUITE 600, WASHINGTON, DC, 20006-1004, US

(73) Assignee: Samsung Mobile Display Co., Ltd., Yongin-city (KR)

(21) Appl. No.: 12/654,939

(22) Filed: Jan. 8, 2010

(30) Foreign Application Priority Data
Jan. 12, 2009 (KR) 10-2009-0002243

(51) Int. Cl. H01L 33/00; H01L 29/786

(52) U.S. Cl. 257/43; 257/59; 257/E29.296; 257/E33.019

(57) ABSTRACT

An oxide semiconductor thin film transistor and a flat panel display device incorporating the same oxide semiconductor thin film transistor. The thin film transistor includes a gate electrode formed on the substrate, a gate insulating layer formed on the substrate and covering the gate electrode, an oxide semiconductor layer formed on the gate insulating layer and covering the gate electrode, a titanium layer formed in a source region and a drain region of the oxide semiconductor layer, and source and drain electrodes respectively coupled to the source region and the drain region through the titanium layer and made of copper. The titanium layer reduces the contact resistance between the source and drain electrodes made of copper and the oxide semiconductor layer, forms a stable interface junction therebetween, and blocks a diffusion of copper.

### CLAIM OF PRIORITY

This application makes reference to, incorporates into this specification the entire contents of, and claims all benefits accruing under 35 U.S.C. §119 from an application earlier filed in the Korean Intellectual Property Office on Jan. 12, 2009, and there duly assigned Serial No. 10-2009-0002243.

### BACKGROUND OF THE INVENTION

1. Field of the Invention

The present invention relates to a thin film transistor and a flat panel display incorporating the same thin film transistor, and more particularly, to an oxide semiconductor thin film transistor to which a copper (Cu) wire is applied, and a flat panel display device incorporating the same thin film transistor.

2. Description of the Related Art

A thin film transistor is generally constructed with a semiconductor layer in which a channel region, a source region and a drain region are provided, a gate electrode that is overlapped with the channel region and is insulated from the semiconductor layer by a gate insulating layer, and a source electrode and a drain electrode that is coupled to the semiconductor layer in the source region and the drain region.

The thin film transistor constituted as described above is applied not only to a semiconductor integrated circuit but also to a flat panel display device such as a liquid crystal display device (LCD) or an active-matrix organic light emitting display device (AMOLED).

In the flat panel display device, electrodes and wires such as scan lines and data lines of the thin film transistor are made of metal such as molybdenum (Mo), aluminum (Al) and tungsten (W), or an alloy thereof.

Such a metal or alloy, however, has a high specific resistance of 11 μΩcm so that if resolution and size of the flat panel display device are increased, a problem arises in that a wire resistance is abruptly increased due to the decrease in wire width and the increase in wire length. If the wire resistance is increased, current or voltage applied to a pixel becomes undesirably uneven due to the voltage drop (current-resistance drop, IR drop) so that a defect is generated or an image quality is deteriorated.

Therefore, there is a demand for a study on wire material that can prevent the defect and the deterioration in the image quality of the flat panel display device in accordance with the increase in resolution and size, and a method of manufacturing the same.

### SUMMARY OF THE INVENTION

It is therefore an object of the present invention to provide an improved thin film transistor and an improved flat panel display device incorporating the thin film transistor.

It is another object of the present invention to provide a thin film transistor that can prevent a voltage drop in accordance with decrease in wire width and increase in wire length, and a flat panel display device incorporating the same thin film transistor.

It is still another object of the present invention to provide a thin film transistor to which a copper (Cu) wire having a small specific resistance is applied, and a flat panel display device incorporating the same thin film transistor.

It is a further object of the present invention to provide a thin film transistor in which a copper wire and an oxide semiconductor layer form a stable interface junction to have a small contact resistance and a diffusion of copper to the oxide semiconductor layer can be prevented, and a flat panel display device incorporating the same thin film transistor.

These and other objects may be attained in the practice of the principles of the present invention, with a thin film transistor including a substrate, a gate electrode formed on the substrate, a gate insulating layer formed on the substrate and covering the gate electrode, an oxide semiconductor layer formed on the gate insulating layer and covering the gate electrode, a titanium layer formed in a source region and a drain region of the oxide semiconductor layer, and source and drain electrodes respectively coupled to the source region and the drain region through the titanium layer and made of copper.

The principles of the present invention may be practiced in a flat panel display device which has a thin film transistor. The flat panel display device may be constructed with a first substrate on which a pixel defined by a first conductive line and a second conductive line, and the thin film transistor that controls signals supplied to each pixel and a first electrode coupled to the thin film transistor are formed, a second substrate on which a second electrode is formed, and a liquid crystal layer injected into a space sealed between the first electrode and the second electrode. The thin film transistor includes a gate electrode formed on the first substrate, a gate insulating layer formed on the substrate and covering the gate electrode, an oxide semiconductor layer formed on the gate insulating layer and covering the gate electrode, a titanium layer formed in a source region and a drain region of the oxide semiconductor layer, and source and drain electrodes coupled to the source region and the drain region through the titanium layer and made of copper.

The principles of the present invention may be practiced in a flat panel display device which has a thin film transistor. The flat panel display device includes a first substrate on which a first conductive layer and a second conductive layer, the thin film transistor coupled between the first conductive layer and the second conductive layer, and an organic light emitting device coupled to the thin film transistor and including a first electrode, an organic thin film layer and a second electrode are formed; and a second substrate disposed to be opposed to the first substrate. The thin film transistor includes a gate electrode formed on the first substrate, a gate insulating layer formed on the substrate and covering the gate electrode, an oxide semiconductor layer formed on the gate insulating layer and covering the gate electrode, a titanium layer formed in a source region and a drain region of the oxide semiconductor layer, and source and drain electrodes coupled to the source region and the drain region through the titanium layer and made of copper.

In the oxide semiconductor thin film transistor according to the present invention, wires such as the source and drain electrodes are made of copper having a small specific resistance, and the titanium layer is interposed between the source and drain electrodes made of copper and the oxide semiconductor layer. The titanium layer reduces the contact resistance between the source and drain electrodes and the oxide semiconductor layer, forms a stable interface junction therebetween, and blocks a diffusion of copper. Therefore, the deterioration in the electrical property of the oxide semiconductor layer by the diffusion of copper is prevented and the current-voltage property is improved by the copper wire having a small specific resistance, making it possible to implement a high definition and large-sized flat panel display device of which image quality is improved.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a cross-sectional view of a thin film transistor constructed as an embodiment according to the principles of the present invention;

FIG. 2 is a cross-sectional view of a thin film transistor constructed as another embodiment according to the principles of the present invention;

FIG. 3 is a graph showing the electrical property of the thin film transistor constructed as the embodiment according to the principles of the present invention;

FIG. 4 is a graph showing the electrical property of a thin film transistor constructed as an comparative example;

FIG. 5 is an oblique view of a flat panel display device incorporating a thin film transistor constructed as an embodiment according to the principles of the present invention;

FIGS. 6A and 6B are a plan view and a cross-sectional view of a flat panel display device incorporating a thin film transistor constructed as another embodiment according to the principles of the present invention; and

FIG. 7 is a cross-sectional view of an organic light emitting display device included in the flat panel display device of FIG. 6A.

### DETAILED DESCRIPTION OF THE INVENTION

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. In addition, when an element is referred to as being “on” another element, the element can be directly on the another element or be indirectly on the another element with one or more intervening elements interposed therebetween. Also, when an element is referred to as being “connected to” another element, the element can be directly connected to the another element or be indirectly connected to the another element with one or more intervening elements interposed therebetween. Hereinafter, like reference numerals refer to like elements.

Recently, a study on an oxide semiconductor thin film transistor has been actively progressed. An oxide semiconductor having zinc oxide (ZnO) as a main ingredient has been evaluated as a stable material having an amorphous shape. The use of the oxide semiconductor lead to various advantages in manufacturing process in that a thin film transistor can be made at a low temperature using a contemporary process equipment, without buying a separate equipment additionally, and an ion implantation process can be omitted, and so on.

Together with the oxide semiconductor, a study on usage of a copper (Cu) wire having a smaller specific resistance rather than molybdenum (Mo) or aluminum (Al) has also been actively progressed in order to reduce the wire resistance.

If the cooper wire is applied to the oxide semiconductor thin film transistor, however, an interface junction between the copper wire (for example, a source electrode and a drain electrode) and the oxide semiconductor becomes defective and electrical property of the oxide semiconductor is undesirably deteriorated due to the diffusion of copper atoms during an annealing process. In other words, a contact resistance between the copper wire and the oxide semiconductor is increased by the defective interface junction, and p-type copper atoms are diffused to an n-type oxide semiconductor so that the electrical property of the oxide semiconductor is deteriorated.

Therefore, in order to apply the cooper wire to the oxide semiconductor thin film transistor, there is a demand for a technical development that can solve the problems as described above.

Hereinafter, exemplary embodiments according to the present invention will be described in detail with reference to the accompanying drawings.

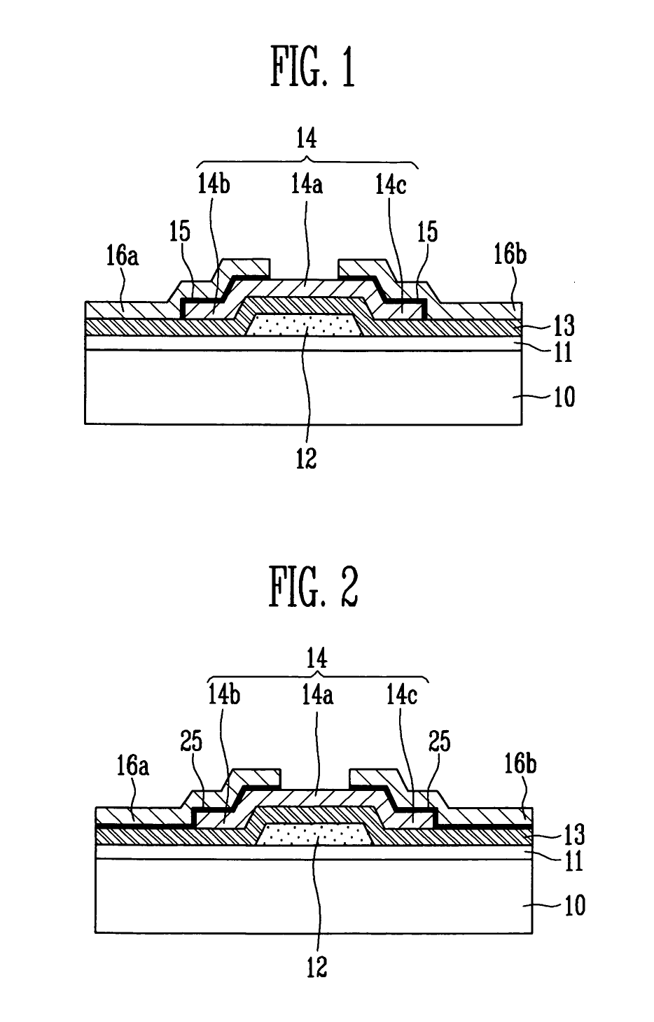

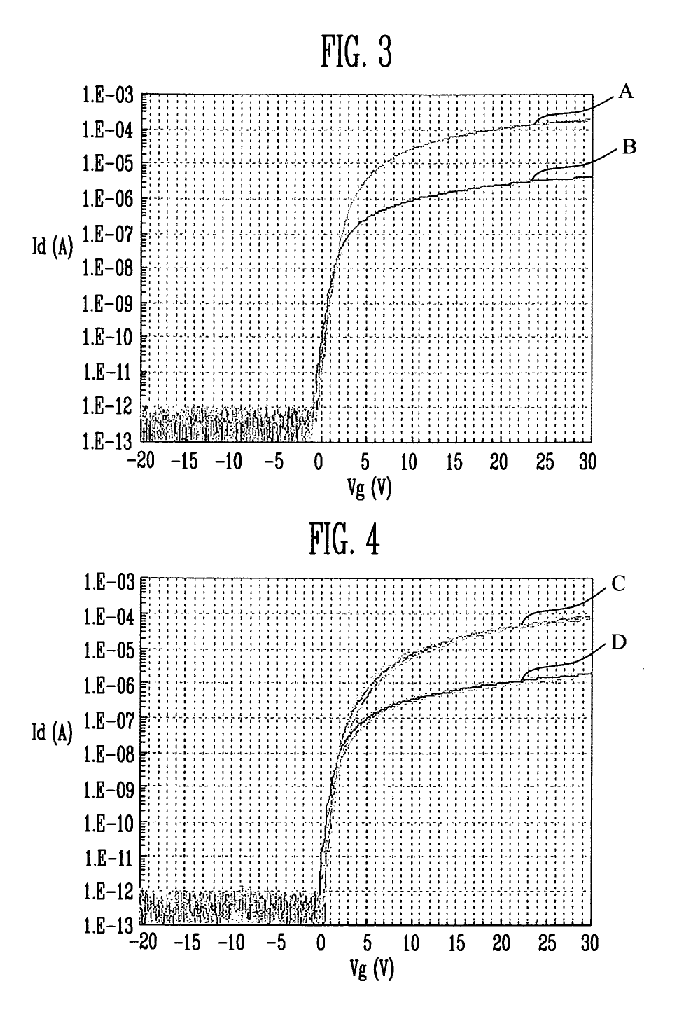

FIG. 1 is a cross-sectional view of a thin film transistor constructed as an embodiment according to the principles of the present invention. FIG. 2 is a cross-sectional view of a thin film transistor constructed as another embodiment according to the principles of the present invention.

Referring to FIG. 1, a buffer layer 11 is formed on a substrate 10, and a gate electrode 12 is formed on buffer layer 11. A gate insulating layer 13 is formed on the entire substrate and covering gate electrode 12, and an oxide semiconductor layer 14 is formed on gate insulating layer 13 and covering gate electrode 12. Oxide semiconductor layer 14 functions as an activation layer in which a channel region 14a, a source region 14b, and a drain region 14c are provided. A titanium (Ti) layer 15 is formed on oxide semiconductor layer 14 in source region 14b and drain region 14c, and source and drain electrodes 16a and 16b made of copper (Cu) are formed to be coupled to source region 14b and drain region 14c, respectively, through titanium layer 15.

FIG. 1 shows a structure where titanium layer 15 is formed only on oxide semiconductor layer 14 in source region 14b and drain region 14c, and FIG. 2 shows a structure where a titanium layer 25 overlaps the entirety of the bottom surface of source and drain electrodes 16a and 16b. The structure shown in FIG. 2 can be formed by patterning titanium layer 25 and source and drain electrodes 16a and 16b by using one mask, making it possible to reduce the number of masks and process steps for fabricating the thin film transistor compared to that of the structure shown in FIG. 1.

Substrate 10 may be formed of a semiconductor substrate such as silicon (Si), etc., an insulating substrate such as glass or plastic, etc., or a metal substrate. Gate electrode 12 may be made of metal such as Al, Cr, MoW, etc. Gate insulating layer 13 may be formed of insulating material such as SiO₂, SiNₓ, Ga₂O₃, etc.

Oxide semiconductor layer 14 may include zinc oxide (ZnO) and may be doped with one ion selected from a group of gallium (Ga), indium (In), stannum (Sn), zirconium (Zr), hafnium (Hf), cadmium (Cd), silver (Ag), copper (Cu), germanium (Ge), gadolinium (Gd), and vanadium (V). Oxide semiconductor layer 14 may be made of ZnO, ZnGaO, ZnInO, ZnSnO, GaInZnO, CdO, InO, GaO, SnO, AgO, CuO, GeO, GdO, and HfO by way of example.

Titanium layers 15 and 25 may have a thickness that is changed during a subsequent process such as an annealing process so that it is preferable that titanium layers 15 and 25 are deposited in consideration of the change in thickness.

As described above, in the thin film transistor according to the present invention, the activation layer is formed of oxide semiconductor layer 14, source and drain electrodes 16a and 16b are made of copper (Cu), and titanium layers 15 and 25 are interposed between oxide semiconductor layer 14 and source and drain electrodes 16a and 16b.

In the thin film transistor having the structure as described above, titanium layers 15 and 25 reduce the contact resistance between source and drain electrodes 16a and 16b and oxide semiconductor layer 14.

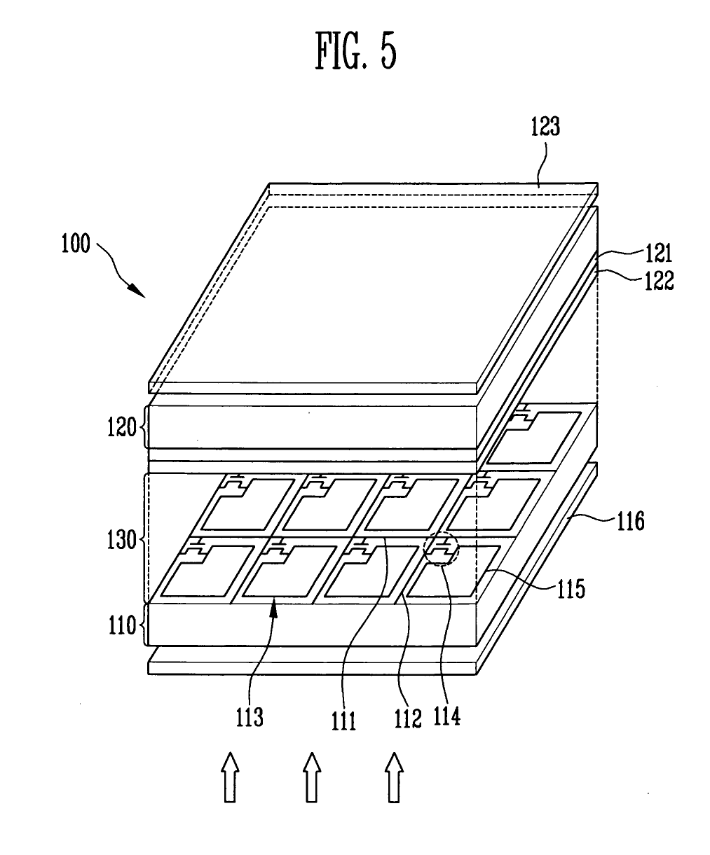

FIGS. 3 and 4 are graphs showing changes in drain current Id, measured in amperes, as a function of the gate voltage Vg, measured in volts, of different thin film transistors. In FIGS. 3 and 4, an individual curve represents one current-voltage measurement of the same thin film transistor. The thin film transistors represented by FIG. 3 have structures where titanium layers 15 and 25 are interposed between source and drain electrodes 16a and 16b and zinc oxide (ZnO) layer 14 constructed as exemplar embodiments according to the principles of the present invention, and the thin film transistors represented by FIG. 4 have structures where the source and drain electrodes made of molybdenum (Mo) directly contact the zinc oxide (ZnO) layer constructed as a comparative example. Comparing the sections of Vg=10V˜30V in FIGS. 3 and 4, the value of Id in FIG. 3 is higher than the value of Id in FIG. 4.

Table 1 summaries threshold voltage, carrier mobility and sub-threshold slope of the thin film transistor constructed as the example of the present invention and the thin film transistor constructed as the comparative example obtained through graphs shown in FIGS. 3 and 4.

TABLE 1

| | Threshold | | | | | |
|---|---|---|---|---|---|---|
| | voltage (V) | | Mobility (cm²/Vs) | | S-Slope (V/Dec) | |
| | Aver- | Standard | Aver- | Standard | Aver- | Standard |
| | age | deviation | age | deviation | age | deviation |
| Mo/ZnO | 1.86 | 0.17 | 7.76 | 1.67 | 0.43 | 0.02 |
| Cu/Ti/ZnO | 1.25 | 0.10 | 15.45 | 1.23 | 0.52 | 0.03 |

Referring to Table 1, the negative shift of the threshold voltage Vth_sat from the comparative example to the example of the present invention means that charge is easily injected to the oxide semiconductor layer of the thin film transistor of the present invention. The increase in the mobility from the example of the present invention to the comparative example means that the amount of charges injected to the oxide semiconductor layer of the thin film transistor of the present invention is increased. Therefore, it can be appreciated that the contact resistance in a structure where titanium (Ti) contacts zinc oxide (ZnO) (FIG. 3) is reduced by twice or three times compared to a structure where molybdenum (Mo) electrode directly contacts zinc oxide (ZnO) (FIG. 4).

Also, in the thin film transistor having the structure as described according to FIGS. 1 and 2, titanium layers 15 and 25 allow source and drain electrodes 16a and 16b and oxide semiconductor layer 14 to have a stable junction and block a diffusion of copper.

Titanium (Ti) forms an excellent interface junction with copper (Cu) and zinc oxide (ZnO), thereby allowing source and drain electrodes 16a and 16b and oxide semiconductor layer 14 to have a stable interface junction. Also, titanium (Ti) functions as a trap that blocks the diffusion of copper (Cu), thereby efficiently blocking the diffusion of copper to oxide semiconductor layer 14.

Therefore, the current-voltage property is improved by the copper wire having a low specific resistance and the deterioration in the property of the oxide semiconductor layer by the diffusion of copper is prevented, thereby making it possible to implement the thin film transistor having an improved electrical property.

FIG. 5 is an oblique view of a flat panel display device to which a thin film transistor according to an embodiment of the principles of the present invention is applied. The flat panel display device will be schematically described as centering on a display panel 100 that displays an image.

Display panel 100 includes two substrates 110 and 120, opposed to each other, and a liquid crystal layer 130 interposed between two substrates 110 and 120. A pixel region 113 is defined by a plurality of gate lines 111 and data lines 112 arranged on substrate 110 in a matrix type. Thin film transistors 114 that control signals supplied to each pixel, and pixel electrodes 115 that are coupled to thin film transistors 114 are formed on substrate 110 in the portions where gate lines 111 and data lines 112 are intersected. Thin film transistor 114 is formed in any one structure as shown in FIGS. 1 and 2, and gate lines 111 or data lines 112 may be made of copper (Cu) during the process that source and drain electrodes 16a and 16b of thin film transistor 114 are formed.

Also, a color filter 121 and a common electrode 122 are formed on substrate 120. Polarization plate 116 is formed on a rear surface of substrate 110, and polarization plate 123 is formed on a front surface of substrate 120. A backlight unit (not shown) is disposed on a rear side of polarization plate 116 as a light source.

Meanwhile, a driver (LCD drive IC, not shown) that drives display panel 100 is mounted to the peripheral of pixel region 113. The driver converts electrical signals supplied from the external to supply them to gate lines 111 and data lines 112.

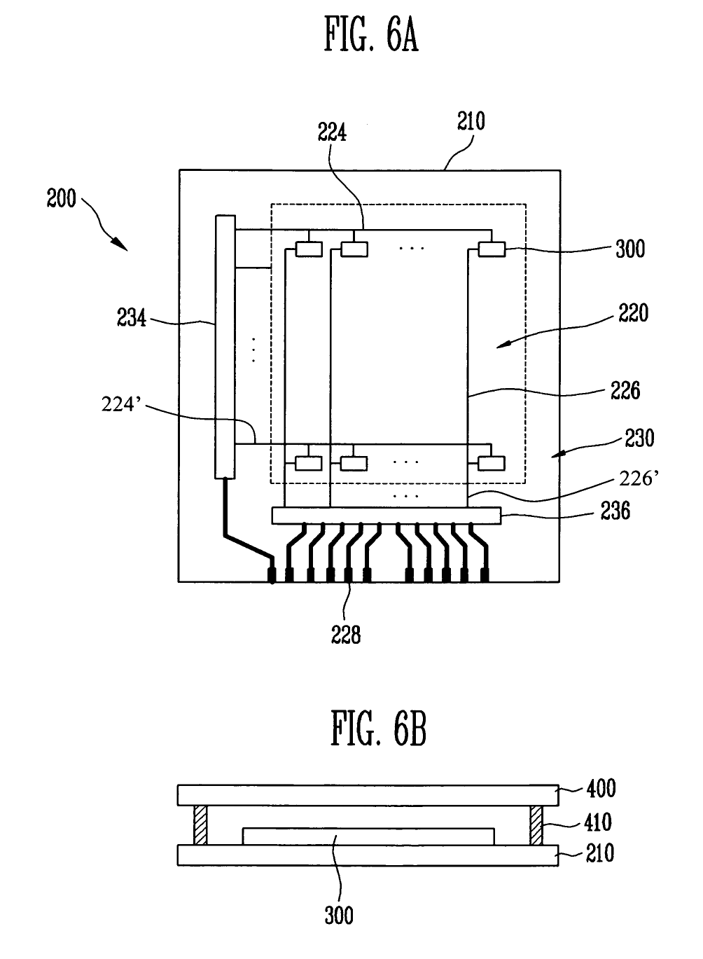

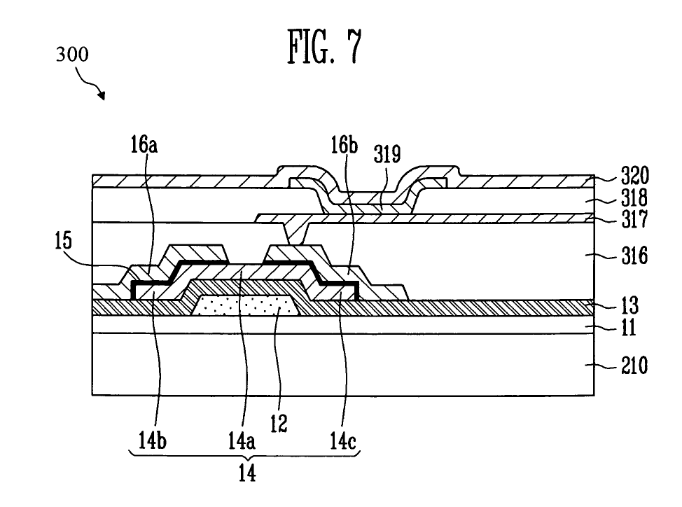

FIGS. 6A and 6B are a plan view and a cross-sectional view of a flat panel display device to which a thin film transistor according to the embodiment of the principles of the present invention is applied. The flat panel display device will be schematically described as centering on a display panel 200 that displays an image.

Referring to FIG. 6A, a substrate 210 is defined as a pixel region 220, and a non-pixel region 230 peripheral to pixel region 220. A plurality of organic light emitting devices 300 coupled between scan lines 224 and data lines 226 in a matrix type are formed on substrate 210 in pixel region 220. Scan lines 224′ and data lines 226′ that respectively extend from scan lines 224 and data lines 226 in pixel region 220, power supply lines (not shown) that operate organic light emitting devices 300, and a scan driver 234 and a data driver 236 that process signals supplied from an exterior region through pads 228 to supply the signals to scan lines 224 and data lines 226, are formed on substrate 210 in non-pixel region 230.

Referring to FIG. 7, organic light emitting device 300 includes an anode electrode 317, a cathode electrode 320, and an organic thin film layer 319 formed between anode electrode 318 and cathode electrode 320. Organic thin film layer 319 is formed in a structure where a hole transport layer, an organic light emitting layer, and an electron transport layer are stacked. A hole injection layer and an electron injection layer may further be included in organic thin film layer 319. Also, a thin film transistor coupled between scan line 224 and data line 226 in order to control the operation of organic light emitting device 300, and a capacitor that maintains a signal, may further included in organic light emitting device 300. The thin film transistor is formed in any one structure as shown in FIGS. 1 and 2.

Organic light emitting device 300 including the thin film transistor constituted as described above will be described in more detail with reference to FIGS. 6A and 7.

A buffer layer 11 is formed on a substrate 210 in a pixel region 220, and a gate electrode 12 is formed on buffer layer 11. At this time, a scan line 224 that is coupled to gate electrode 12 may be formed in pixel region 220. A scan line 224′ that extends from scan line 224 in pixel region 220, and a pad 228 that receives signal from an exterior part may be formed in a non-pixel region 230.

A gate insulating layer 13 is formed on the entire substrate and covering gate electrode 12, and an oxide semiconductor layer 14 is formed on gate insulating layer 13. A titanium layer 15 is formed on oxide semiconductor layer 14 in source region 14b and drain region 14c. Source and drain electrodes 16a and 16b are formed to be coupled to source region 14b and drain region 14c through titanium layer 15. At this time, a data line 226 that is coupled to source and drain electrodes 16a and 16b may be formed in pixel region 220, and a data line 226′ extending from data line 226 in pixel region 220 and pad 228 that receives a signal supplied from an exterior region may be formed in non-pixel region 230. Source and drain electrodes 16a and 16b, data line 226 and pad 228 are made of copper (Cu).

Thereafter, a planarization layer 316 that planarizes a surface is formed on the entirety of the upper surface of pixel region 220. On planarization layer 316, a via hole is formed in order that a predetermined portion of source or drain electrode 16a or 16b is exposed, and anode electrode 317 coupled to source or drain electrode 16a or 16b through the via hole is formed.

A pixel definition layer 318 is formed on planarization layer 316 in order that a partial region (a light emitting region) of anode electrode 317 is exposed. An organic light emitting layer 319 is formed on anode electrode 317. A cathode electrode 320 is formed on pixel definition layer 319 in which organic thin film layer 319 is included.

Referring to FIG. 6B, a sealing substrate 400 that seals pixel region 220 is disposed on the upper portion of substrate 210 on which organic light emitting device 300 is formed as described above, and sealing substrate 400 is bonded to substrate 210 by a sealant 410, thereby completing display panel 200.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A thin film transistor, comprising:
a substrate;
a gate electrode formed on the substrate;
a gate insulating layer formed on the substrate and covering the gate electrode;
an oxide semiconductor layer formed on the gate insulating layer and covering the gate electrode;
a titanium layer formed in a source region and a drain region of the oxide semiconductor layer; and
source and drain electrodes electrically coupled to the source region and the drain region, respectively, through the titanium layer and made of copper.

2. The thin film transistor as claimed in claim 1, further comprising a buffer layer formed on the substrate.

3. The thin film transistor as claimed in claim 1, wherein the oxide semiconductor layer includes zinc oxide (ZnO).

4. The thin film transistor as claimed in claim 3, wherein the oxide semiconductor is doped with at least one ion selected from a group of gallium (Ga), indium (In), stannum (Sn), zirconium (Zr), hafnium (Hf), cadmium (Cd), silver (Ag), copper (Cu), germanium (Ge), gadolinium (Gd), and vanadium (V).

5. The thin film transistor as claimed in claim 1, wherein the titanium layer overlaps the entire bottom surface of the source and drain electrodes.

6. A flat panel display device, comprising:
a first substrate on which a pixel defined by a first conductive line and a second conductive line is formed;
a thin film transistor formed on the first substrate and controlling signals supplied to each pixel and a first electrode coupled to the thin film transistor are formed;
a second substrate on which a second electrode is formed; and
a liquid crystal layer injected into a space sealed between the first electrode and the second electrode,
wherein the thin film transistor comprises:
a gate electrode formed on the first substrate;
a gate insulating layer formed on the substrate and covering the gate electrode;
an oxide semiconductor layer formed on the gate insulating layer and covering the gate electrode;
a titanium layer formed in a source region and a drain region of the oxide semiconductor layer; and
source and drain electrodes electrically coupled to the source region and the drain region, respectively, through the titanium layer and made of copper.

7. The flat panel display device as claimed in claim 6, further comprising a buffer layer formed on the first substrate.

8. The flat panel display device as claimed in claim 6, wherein at least one of the first conductive layer and the second conductive layer is made of copper.

9. The flat panel display device as claimed in claim 6, wherein the oxide semiconductor layer includes zinc oxide (ZnO).

10. The flat panel display device as claimed in claim 9, wherein the oxide semiconductor is doped with at least one ion selected from a group of gallium (Ga), indium (In), stannum (Sn), zirconium (Zr), hafnium (Hf), cadmium (Cd), silver (Ag), copper (Cu), germanium (Ge), gadolinium (Gd), and vanadium (V).

11. The flat panel display device as claimed in claim 6, wherein the titanium layer overlaps the entire bottom surface of the source and drain electrodes.

12. A flat panel display device, comprising:
a first substrate on which a first conductive layer and a second conductive layer, a thin film transistor coupled between the first conductive layer and the second conductive layer, and an organic light emitting device coupled to the thin film transistor and formed of a first electrode, an organic thin film layer, and a second electrode are formed; and
a second substrate disposed to be opposed to the first substrate,
wherein the thin film transistor comprises:
a gate electrode formed on the first substrate;
a gate insulating layer formed on the substrate and covering the gate electrode;
an oxide semiconductor layer formed on the gate insulating layer and covering the gate electrode;
a titanium layer formed in a source region and a drain region of the oxide semiconductor layer; and
source and drain electrodes coupled to the source region and the drain region through the titanium layer and made of copper.

13. The flat panel display device as claimed in claim 12, further comprising a buffer layer formed on the first substrate.

14. The flat panel display device as claimed in claim 12, wherein at least one of the first conductive layer and the second conductive layer is made of copper.

15. The flat panel display device as claimed in claim 12, wherein the oxide semiconductor layer includes zinc oxide (ZnO).

16. The flat panel display device as claimed in claim 15, wherein the oxide semiconductor is doped with at least one ion selected from gallium (Ga), indium (In), stannum (Sn), zirconium (Zr), hafnium (Hf), cadmium (Cd), silver (Ag), copper (Cu), germanium (Ge), gadolinium (Gd), and vanadium (V).

17. The flat panel display device as claimed in claim 12, wherein the titanium layer is overlapped with the entire bottom surface of the source and drain electrodes.
